(19) United States
(12) Patent Application Publication
(10) Pub. No.: US 2025/0308606 A1
(43) Pub. Date: Oct. 2, 2025

(54) MEMORY DEVICE, OPERATION METHOD THEREOF AND MEMORY SYSTEM

(71) Applicant: YANGTZE MEMORY TECHNOLOGIES CO., LTD., Wuhan (CN)

(72) Inventors: Teng CHEN, Wuhan (CN); Ke LIANG, Wuhan (CN)

(21) Appl. No.: 18/768,369

(22) Filed: Jul. 10, 2024

(30) Foreign Application Priority Data
Mar. 29, 2024 (CN) 2024103816528

(51) Int. Cl. G11C 16/34; G11C 16/04

(52) U.S. Cl. CPC G11C 16/349; G11C 16/0483

(57) ABSTRACT

Implementations of the present disclosure disclose a memory device, an operation method thereof and a memory system. The memory device includes a peripheral circuit. The peripheral circuit includes a set of page buffers, an error bit signal generating circuit and a plurality of first transistors, wherein the set of page buffers includes N page buffers with N being an integer larger than 1, the error bit signal generating circuit is connected with the sensing nodes of the page buffers, and the respective sensing nodes of every two adjacent page buffers in the set of page buffers are connected with one of the first transistors.

### CROSS-REFERENCE TO RELATED APPLICATIONS

The present application claims priority to Chinese Patent Application No. 2024103816528, which was filed Mar. 29, 2024, is titled “MEMORY DEVICE AND ITS OPERATING METHOD, MEMORY SYSTEM,” and is hereby incorporated herein by reference in its entirety.

### TECHNICAL FIELD

Implementations of the present disclosure relate to semiconductor technology and in particular, but not limited to, a memory device, an operation method thereof and a memory system.

### BACKGROUND

Semiconductor memories are roughly classified into two categories depending on whether they retain the stored data when power is off. The two categories of semiconductor memories are volatile memories, which lose the stored data when power is off, and nonvolatile memories, which retain the stored data when power is off. Memory cells in nonvolatile memories are connected to bit lines and word lines respectively and thus have good random access characteristics.

### SUMMARY

In view of this, implementations of the present disclosure provide a memory device, an operation method thereof and a memory system.

In the first aspect, implementations of the present disclosure provide a memory device including a peripheral circuit that includes a set of page buffers, an error bit signal generating circuit and a plurality of first transistors, wherein the set of page buffers includes N page buffers with N being an integer larger than 1, the error bit signal generating circuit is connected with the sensing nodes of the page buffers, and the respective sensing nodes of every two adjacent page buffers in the set of page buffers are connected by one of the first transistors.

In the second aspect, implementations of the present disclosure further provide a memory system including the memory device in any of the implementations described above and a memory controller coupled to the memory device and configured to control the memory device.

In the third aspect, implementations of the present disclosure further provide a method of operating a memory device, the method includes: at the stage of error bit counting operation, receiving a first voltage at a sensing node of a page buffer to be counted; after the first voltage is received at the sensing node, generating a second voltage at the sensing node of the page buffer to be counted based on the information stored in the page buffer; and receiving the second voltage by an error bit signal generating circuit and generating a current signal based on the second voltage being smaller than the first voltage.

The sensing node of each page buffer in a set of page buffers of implementations of the present disclosure is connected directly or indirectly to the error bit signal generating circuit through at least one first transistor. At both the stage of performing error bit counting and the stage of performing non-error bit counting, the information stored in a page buffer can be sensed through the sensing node in the page buffer and in implementations of the present disclosure by multiplexing at the sensing nodes of the page buffers, the number of circuit elements in the page buffer is reduced while retaining the original functions of the page buffer, enabling miniaturization of the page buffer and reducing the area occupied by the peripheral circuit. For example, in case that the peripheral circuit has the same area, there may be more spare area for arrangement of other circuit elements, facilitating to enrich functions of the peripheral circuit.

### BRIEF DESCRIPTION OF THE DRAWINGS

In the accompanying drawings, similar reference numerals may designate similar components in different figures. Similar reference numerals with different character suffixes may designate different instances of similar components. For the purpose of illustration rather than limitation, the accompanying drawings illustrate generally individual implementation to be discussed herein.

FIG. 1A is a structural diagram of an example system according to an implementation of the present disclosure;

FIG. 1B is a structural diagram of a memory card according to an implementation of the present disclosure;

FIG. 1C is a structural diagram of a solid state disk (SSD) according to an implementation of the present disclosure;

FIGS. 1D and 1E are structural diagrams of a memory including a memory cell array and a peripheral circuit according to an implementation of the present disclosure;

FIG. 1F is a structural diagram of a memory including page buffers according to an implementation of the present disclosure;

FIGS. 2A and 2B (which may be collectively referred to herein as FIG. 2) are a schematic diagram of a set of page buffers according to an example implementation;

FIG. 3 is a schematic diagram of an error bit signal generating circuit according to an example implementation;

FIG. 4 is a schematic diagram illustrating waveforms of a Prechb_ver signal and a Verchk signal according to an example Implementation;

FIG. 5 is the first structural diagram of a set of page buffers and an error bit signal generating circuit according to an implementation of the present disclosure;

FIGS. 6A, 6B, 6C, and 6D (which may be collectively referred to herein as FIG. 6) are the second structural diagram of a set of page buffers and an error bit signal generating circuit according to an implementation of the present disclosure;

FIG. 7 is a structural diagram of a page buffer according to an implementation of the present disclosure;

FIG. 8 is a schematic diagram illustrating a connection relationship between a set of page buffers and an error bit signal generating circuit according to an implementation of the present disclosure;

FIG. 9 is a schematic diagram illustrating waveforms of voltages applied on the gate terminals of a plurality of first transistors and a plurality of second transistors in a set of page buffers during an error bit counting operation executed by the set of page buffers according to an implementation of the present disclosure;

FIG. 10 is a structural diagram of an error bit signal generating circuit according to an implementation of the present disclosure;

FIG. 11 is a schematic diagram illustrating channel distribution of a set of page buffers and an error bit signal generating circuit according to some implementations;

FIG. 12 is a schematic diagram illustrating channel distribution of a set of page buffers and an error bit signal generating circuit according to an implementation of the present disclosure; and

FIG. 13 is a flow chart of a method of operating a memory device according to an implementation of the present disclosure.

### DETAILED DESCRIPTION

In order to facilitate its understanding, the present disclosure will be described more fully with reference to related accompanying drawings hereafter. Preferred implementations of the present disclosure are shown in the accompanying drawings. However, the present disclosure may be embodied in various forms without being limited to the implementations to be described herein. Instead, the implementations are provided to make disclosure of the present invention more thorough and complete.

All the technical and scientific terms used herein have the same meanings as those commonly understood by those of ordinary skills in the technical field, to which the present disclosure belongs, unless otherwise defined. Terms used in the specification of the present disclosure are only for the purpose of describing implementations rather than limiting the present disclosure. The term “and/or” as used herein includes any and all combinations of one or more related listed items.

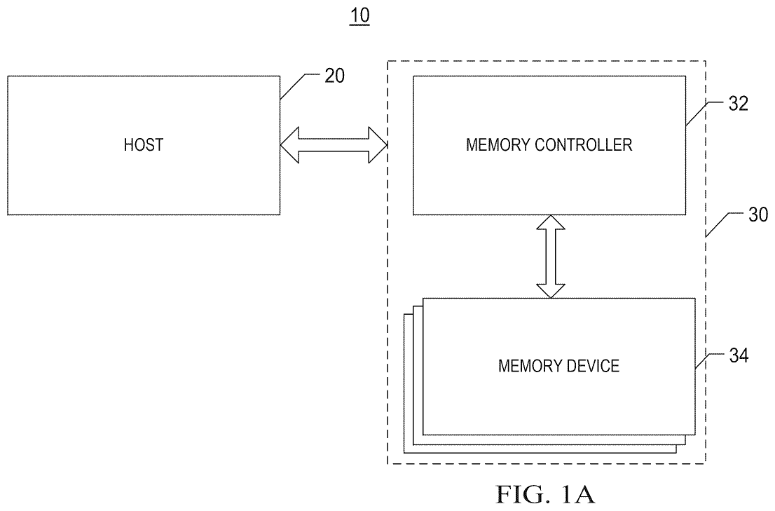

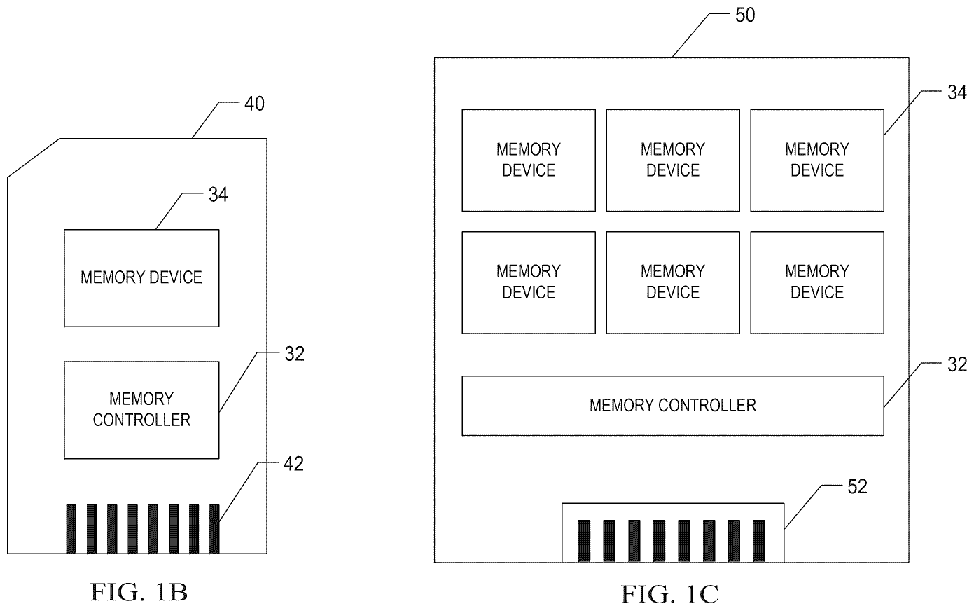

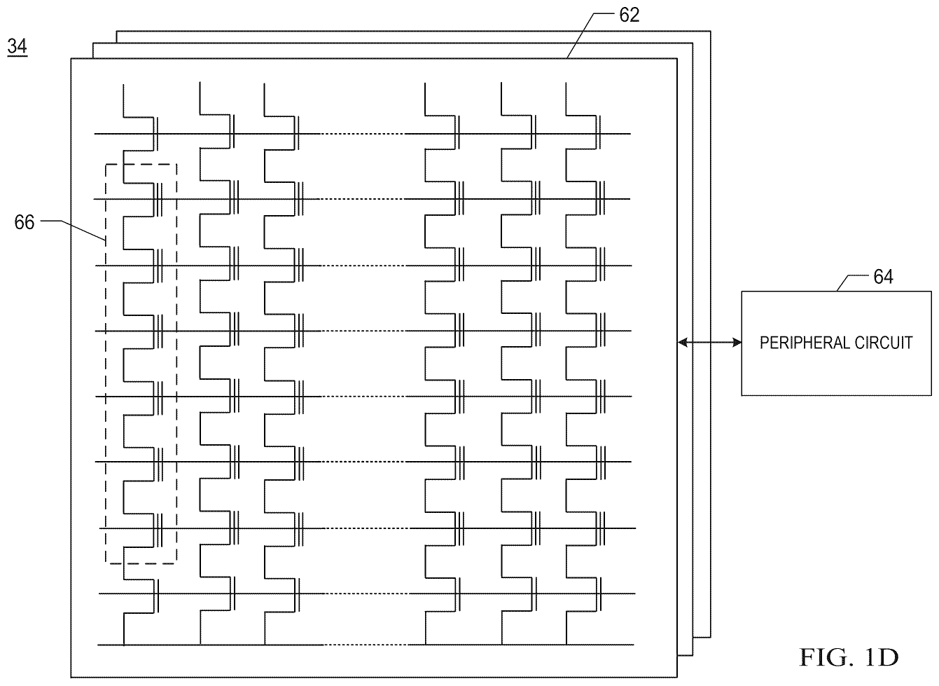

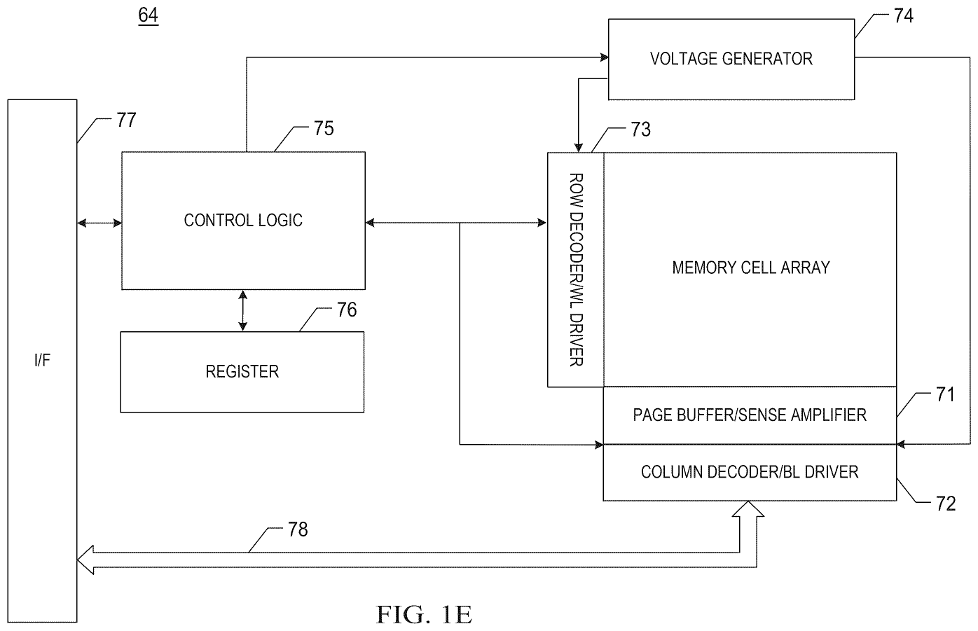

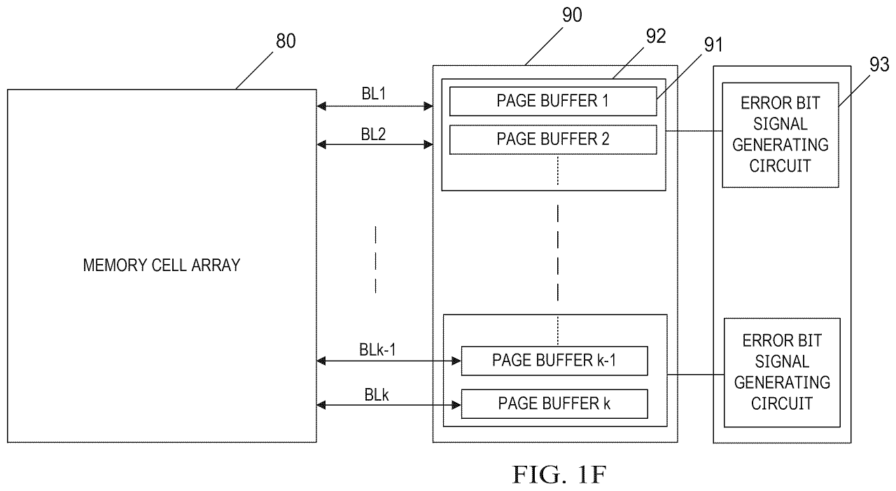

As shown in FIG. 1, an implementation of the present disclosure illustrates an example system 10 including a host 20 and a memory system 30. Here, the example system 10 may include, but is not limited to, a mobile phone, a desk computer, a laptop computer, a tablet computer, a vehicle computer, a gaming console, a printer, a positioning device, a wearable electronic device, a smart sensor, a virtual reality (Virtual Reality, VR) device, an augment reality (Augmented Reality, AR) device, or any other suitable electronic device having a memory device 34 therein. The host 20 may be a processor of an electronic device such as a central processing unit (CPU), or a system-on-chip (SoC) such as an application processor (AP).

In an implementation of the present disclosure, the host 20 may be configured to send data to the memory system 30 or receive data from the memory system 30. Here, the memory system 30 may include a memory controller 32 and one or more memory devices 34. The memory device 34 may include, but not limited to, a NAND flash memory, a vertical NAND flash memory, an NOR flash memory, a dynamic random access memory (DRAM), a ferroelectric random access memory (FRAM), a magnetoresistive random access memory (MRAM), a phase change random access memory (PCRAM), a resistive random access memory (RRAM), a nano random access memory (NRAM) etc.

In an implementation of the present disclosure, the memory controller 32 may be coupled to the memory device 34 and the host 20 and configured to control the memory device 34. Illustratively, the memory controller 32 may be designed for operating in a low duty-cycle environment like a secure digital (SD) card, a compact flash (CF) card, a universal serial bus (USB) flash drive or any other medium for use in an electronic device such as a personal computer, a digital camera, a mobile phone, etc. In some implementations, the memory controller 32 can also be designed for operating in a high duty-cycle environment like an SSD or an embedded multi-media-card (eMMC), used as a data storage for a mobile device such as a smart phone, a tablet computer or a laptop computer, and an enterprise storage array.

Further, the memory controller 32 can manage the data in the memory device 34 and communicate with the host. The memory controller 32 may be configured to control operations of the memory device 34 such as reading, erasing and programing; manage various functions with respect to the data stored or to be stored in the memory device 34 including, but not limited to, bad-block management, garbage collection, logical-to-physical address conversion, wear leveling, etc.; and process error correction codes (ECCs) with respect to the data read from or written to the memory device 34. In addition, the memory controller 32 may also perform any other suitable functions, for example, formatting the memory device 34, or may communicate with an external device (e.g., the host 20 in FIG. 1A) according to a particular communication protocol. Illustratively, the memory controller 32 may communicate with an external host through at least one of various interface protocols, such as a USB protocol, an MMC protocol, a peripheral component interconnect (PCI) protocol, a peripheral component interconnect express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated development equipment (DE) protocol, a Firewire protocol, etc.

In an implementation of the present disclosure, the memory controller 32 and the one or more memory devices 34 can be integrated into various types of storage apparatuses, for example, be included in a same package, such as a universal flash storage (UFS) package or an eMMC package. For example, the memory system 30 can be implemented and packaged into different types of electronic end products. As shown in FIG. 1B, the memory controller 32 and a single memory device 34 may be integrated together to form a memory card 40. The memory card 40 may include a PC card (the personal computer memory card international association), a CF card, a smart media (SM) card, a memory stick, a multi-media card (MMC), a reduced-size MMC (RS-MMC), an MMCmicro, an SD (SD, miniSD, microSD, SDHC (Secure Digital High Capacity)) card, a UFS etc. The memory card 40 may further include a memory card connector 42 coupling the memory card 40 with a host (e.g., the host 20 in FIG. 1A). In another implementation as shown in FIG. 1C, the memory controller 32 and a plurality of memory devices 34 may be integrated together to form an SSD 50. The SSD 50 may further include an SSD connector 52 coupling the SSD 50 with a host (e.g., the host 20 in FIG. 1A). In some implementations, the storage capacity and/or the operation speed of the SSD 50 are greater than those of the memory card 40.

It is to be noted that any memory involved in the implementation of the present disclosure may be a semiconductor memory that is a solid electronic device fabricated to store data information using semiconductor integrated circuit processes. Illustratively, FIG. 1D is a schematic diagram of an optional memory device 34 according to an implementation of the present disclosure. As shown in FIG. 1D, the memory device 34 may include a memory array 62, a peripheral circuit 64 coupled to the memory array 62 and the like. Here, the memory array may be a NAND flash memory array, in which memory cells are arranged in the form of an array of NAND memory strings 66 each extending vertically above a substrate. In some implementations, each NAND memory string 66 includes a plurality of memory cells coupled in series and stacked vertically. Each memory cell can hold a continuous analog value, such as voltage or charge, that depends on the number of electrons trapped within a region of the memory cell. In addition, the memory cell in the above-mentioned memory array 62 may be either a floating gate type of memory cell including a floating-gate transistor or a charge trapping type of memory cell including a charge trapping transistor.

In an implementation of the present disclosure, the above-mentioned memory cell may be a single-level cell (SLC) that has two possible memory states and thus can store one bit of data. For example, the first memory state “0” may correspond to a first range of threshold voltages, and the second memory state “1” may correspond to a second range of threshold voltages. In some implementations, each memory cell may be a multi-level cell (MLC) that is capable of storing more than a single bit of data. For example, an MLC may store two bits each cell. Each memory cell may also be a triple level cell (TLC) or a quad level cell (QLC). Each MLC may be programmed to a range of possible nominal storage values. Illustratively, if each MLC stores two bits of data, then the MLC may be programmed to one of three possible programming levels from an erased state by writing one of three possible nominal storage values to the cell. Here, a fourth nominal storage value may be used to correspond to the erased state.

In an implementation of the present disclosure, the above-mentioned peripheral circuit 64 may be coupled to the memory array through bit lines (BLs), word lines (WLs), source lines, source select gates (SSGs) and drain select gates (DSGs). Here, the peripheral circuit 64 may include any suitable analog, digital, and mixed-signal circuits and thus used to facilitate related operations of the memory array by applying and sensing voltage signals and/or current signals to and from each target memory cell through bit lines, word lines, source lines, SSGs, DSGs or the like. In addition, the peripheral circuit 64 may include various types of peripheral circuit formed using metal-oxide-semiconductor (MOS) technology. Illustratively, it is as shown in FIG. 1E. The peripheral circuit 64 may include a page buffer (PB)/sense amplifier 71, a column decoder/bit line driver 72, a row decoder/word line driver 73, a voltage generator 74, a control logic unit 75, registers 76, an interface 77, and a data bus 78. In some other implementations, the peripheral circuit 64 may further include additional peripheral circuit not shown in FIG. 1E.

As shown in FIG. 1F, a plurality of sets of page buffers 92 and a plurality of error bit signal generating circuits 93 are shown in an implementation of the present disclosure. Each set of page buffers 92 may be connected correspondingly to an error bit signal generating circuit 93. Each set of page buffers 92 includes a plurality of page buffers 91, each of which may be coupled to a memory cell array 80 via a bit line BL, so that the set of page buffers 92 are coupled to the memory cell array 80. For example, page buffers PB1 to PBk may be coupled to a memory cell array via respective bit lines BL1 to BLk. It should be understood that the position relationship between the plurality of sets of page buffers, the plurality of error bit signal generating circuits and the memory cell array described above is only an example and does not represent their actual position relationship. Related arrangement of the plurality of sets of page buffers, the plurality of error bit signal generating circuits and the memory cell array may depend on a specific layout design.

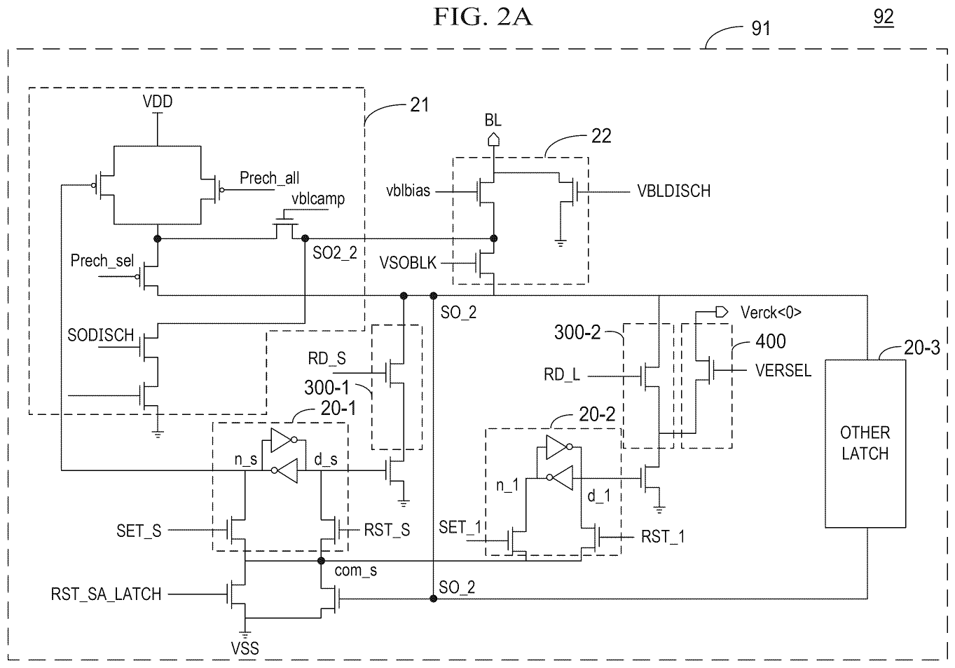

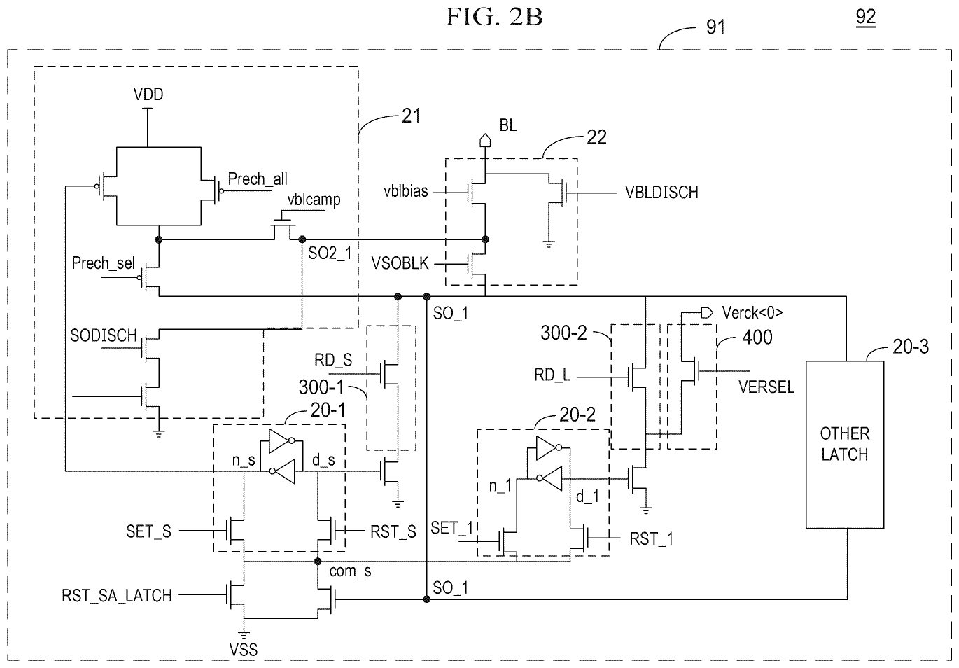

In some implementations, each set of page buffers includes a plurality of page buffers 91. As shown in FIG. 2, each set of page buffers includes two page buffers 91, each of which includes a pre-charging and pre-discharging circuit 21, a bit line voltage setting circuit 22 and a plurality of latches, which may include a sense latch (S Latch) 20-1, a low voltage latch (LVT Latch) 20-2 and/or a set of data latches 20-3. The set of data latches 20-3 may be one of or a combination of a D1 latch, a D2 latch or a cache latch.

The pre-charging and pre-discharging circuit 21 is configured to adjust voltages of the bit lines BL during execution of logical operations (e.g., programming, reading or writing). The pre-charging and pre-discharging circuit 21 is further configured to adjust the voltage at a sensing node SO during execution of logical operations.

In some implementations, the pre-charging and pre-discharging circuit 21 may set the voltage at the sensing node SO directly by sensing the data latched in the sense latch 20-1.

In some implementations, the pre-charging and pre-discharging circuit 21 may set the voltage at the sensing node SO directly without sensing the data latched in the sense latch 20-1. For example, when a Prech_sel signal and a Prech_all signal are enabled simultaneously, a power voltage (VDD) may be applied to the sensing node SO by the pre-charging and pre-discharging circuit 21.

The bit line voltage setting circuit 22 is configured to provide different bit line forcing voltages to bit lines, so that finer programing operations may be performed to the memory cells.

For the implementation shown in FIG. 2, each latch may be connected to the sensing node SO through a first data transfer circuit 300 corresponding to the latch. For example, the sense latch 20-1 is connected to a first one 300-1 of the first data transfer circuits and the low voltage latch 20-2 is connected to a second one 300-2 of the first data transfer circuits. In execution of a non-error bit counting operation, a sense operation may be performed on the connected latch based on the first data transfer circuit 300.

The low voltage latch 20-2 is also connected to a second data transfer circuit 400. In execution of an error bit counting operation, data may be read from the low voltage latch 20-2 and the data stored in the low voltage latch 20-2 may be used to perform the error bit counting operation.

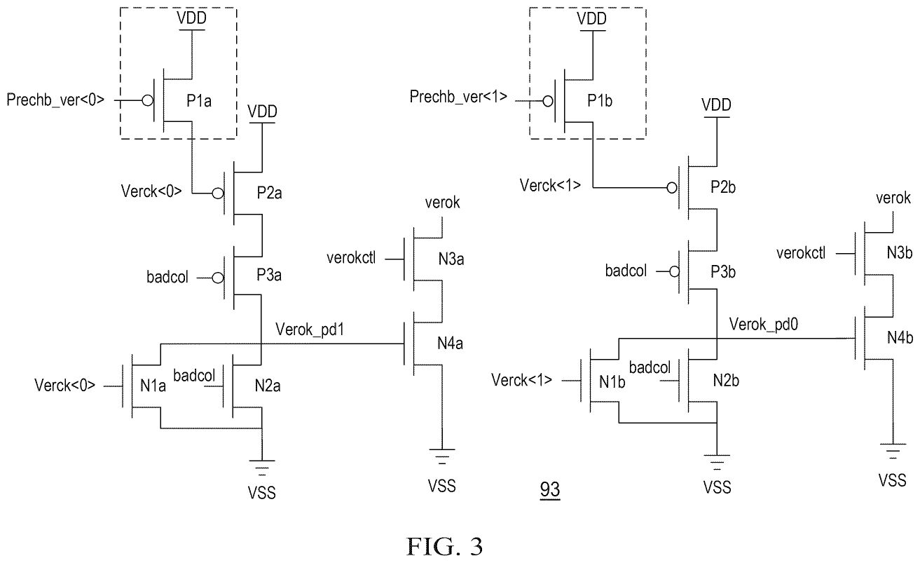

For example, for a set of page buffers as shown in FIG. 2, each set of page buffers perform its error bit counting operations through the respective second data transfer circuits 400. The plurality of second data transfer circuits in each set of page buffers may all connected to the same pull-up node Verck<0>. The pull-up node Verck<0> in the set of page buffers 92 shown in FIG. 2 is connected to the gate terminal of the P2a transistor of the error bit signal generating circuit 93 and the second terminal of the P1a transistor as shown in FIG. 3 (here, the terminal of the P1a transistor that is connected to the power voltage VDD is referred to as the first terminal of the P1a transistor). The P2b transistor in the error bit signal generating circuit 93 shown in FIG. 3 is connected to a pull-up node Verck<1> in another set of page buffers.

In execution of an error bit counting operation, it is necessary to use the charging circuit in the error bit signal generating circuit 93 shown in FIG. 3, which includes P1 transistors (e.g., a P1a transistor and a P1b transistor) for pre-charging the pull-up node of the set of page buffers.

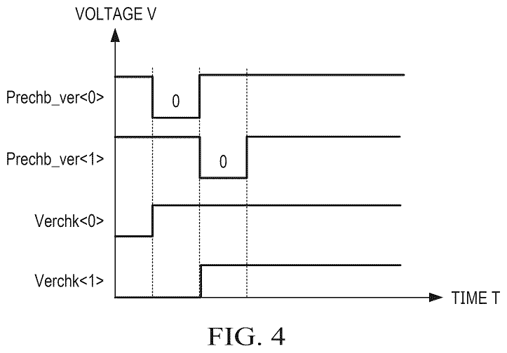

FIG. 4 is a schematic diagram illustrating waveforms of a plurality of Prechb_ver signals and a plurality of Verck signals. The Prechb_ver signals in FIG. 4 are applied to the error bit signal generating circuit 93 shown in FIG. 3. It can be seen that when Prechb_ver<0> transits from a high level to a low level, the P1a transistor is turned on, the power voltage VDD connected to the first terminal of the P1a transistor is transferred to the second terminal of the P1 transistor, and the Verck<0> signal transits from a low level to a high level. When Prechb_ver<0> transits from the low level back to the high level, the Verck<0> signal may float at its high level. The Prechb_ver<1> signal and the Verck<1> signal vary in a similar way.

Hereafter, the process of performing the error bit counting operation on the page buffers to be counted in the set of page buffers will be described in connection with FIGS. 2, 3 and 4.

At first, the pull-up node Verck<0> in the set of page buffers is pre-charged using the P1a transistor in the error bit signal generating circuit 93 shown in FIG. 3 and is charged to the power voltage VDD. Then the Versel transistor in the second data transfer circuit 400 of the page buffer 91 to be counted is turned on. If the voltage at the pull-up node Verck<0> remains at VDD, it is indicated that the data stored at the d_1 node by the low voltage latch 20-2 is “0”. If the voltage at the pull-up node Verck<0> decreases from VDD to a low level, it is indicated that the data stored at the d_1 node by the low voltage latch 20-2 is “1”. In some implementations, the data stored at the d_1 or n_1 node by the low voltage latch 20-2 may be taken as the data stored in the latch and the data stored at the d_1 node is the inverse of the data stored at the n_1 node. In some implementations, if the data stored at the d_1 node is “1”, it can be indicated that verification fails after this program operation. In some other implementations, if the data stored at the d_1 node is “0”, it can be indicated that verification fails after this program operation. The present disclosure is not limited in this aspect.

If the voltage at the pull-up node Verck<0> decreases from VDD to the low level, the P2a transistor in FIG. 3 is turned on, and based on the on state of a P3a transistor (e.g., the P3a transistor may be a P-type transistor that may be turned on based on reception of a badcol signal of a low level, or may be an N-type transistor that may be turned on based on reception of the badcol signal of a high level), the level VDD received at the first terminal of the P2a transistor is transferred to the gate terminal of an N4a transistor, which is thus turned on. The N4a transistor is connected in series with an N3a transistor. Based on the on state of the N3a transistor (e.g., the N3a transistor may be an N-type transistor that may be turned on based on reception of a verokct1 signal of a high level, or may be a P-type transistor that may be turned on based on reception of the veroket1 signal of a low level), a current occurs in this series branch since the N4a transistor is in the on state.

If the voltage at the pull-up node Verck<0> remains at VDD, an Nia transistor is turned on to transfer the ground voltage VSS to the gate terminal of the N4a transistor with the P3a transistor being turned on and the N4a transistor being turned off. The N4a transistor is connected in series with the N3a transistor, the N3a transistor is in the on state, the N4a transistor is in the off state, so that no current occurs in this series branch.

In some implementations, if the error bit signal generating circuit 93 generates a current, it can indicate that verification fails after this program operation. In some other implementations, if the error bit signal generating circuit 93 does not generates current, it can indicate that verification succeeds after this program operation. Therefore, the total number of failing bits (also referred to as the total number of error bits) or the total number of non-failing bits may be obtained based on the total number of currents that occur in a plurality of sets of page buffers.

The set of page buffers 92 and the error bit signal generating circuit 93 described above can be used in cooperation with each other to achieve the function of error bit counting, but they have a too large area. In the context of continuous miniaturization of memory devices and the peripheral circuit, how to reduce the area of the set of page buffers 92 and the error bit signal generating circuit 93 has become an urgent problem to be resolved.

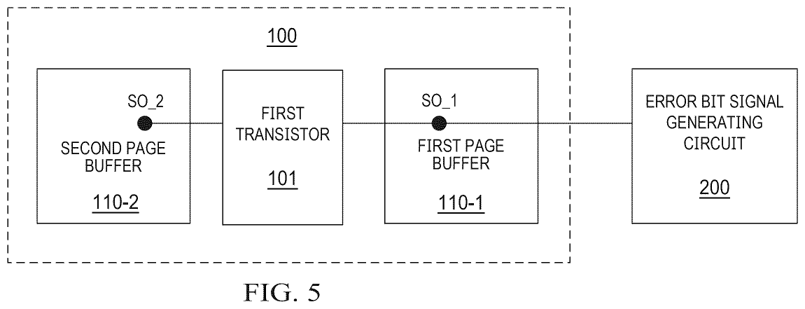

In order to solve the above-described problem, implementations of the present disclosure provide a memory device including a peripheral circuit. As shown in FIG. 5, the peripheral circuit include a set of page buffers 100, an error bit signal generating circuit 200 and a plurality of first transistors 101 with the set of page buffers 100 including N page buffers 110, N being an integer larger than 1. The error bit signal generating circuit 200 is connected to the sensing node SO of each page buffer 110 in the set of page buffers 100, and the respective sensing nodes SO of two adjacent page buffers 110 in the set of page buffers 100 may be connected via one first transistor 101.

FIG. 5 is an implementation in which the set of page buffers 100 includes two page buffers 110. It should be understood that in implementations of the present disclosure the number of page buffers in the set of page buffers 100 may be any positive integer larger than or equal to 2.

In implementations of the present disclosure, the first transistor 101 may be an N-type transistor or a P-type transistor and description will be provided with an N-type transistor as the first transistor 101 being taken as an example.

In implementations of the present disclosure, the respective sensing nodes SO of two adjacent page buffers 110 are connected via one first transistor 101 and the error bit signal generating circuit 200 is directly connected to the sensing node SO_1 of one page buffer 110 (e.g., the first page buffer 110_1). When the first transistor 101 is in the on state, the error bit signal generating circuit 200 is indirectly connected to the sensing node SO_2 of the other page buffer 110 (e.g., the second page buffer 110_2).

In implementations of the present disclosure, when an error bit counting operation is performed on a page buffer 110 to be counted, the sensing node of the page buffer 110 is charged to a first level (e.g., VDD) at first and in some implementations, the charging may be done based on the charging circuit in the error bit signal generating circuit 200. In some other implementations, the sensing node SO may be charged not based on the charging circuit in the error bit signal generating circuit 200. Therefore, in those implementations, compared with the error bit signal generating circuit in FIG. 3, the charging circuit which may include at least one transistor (e.g., the P1 transistor) can be saved. Furthermore, a control circuit for the Prechb_ver signal may further be saved. Also, in those implementations, the peak current introduced by charging the pull-up node verchk may be reduced efficiently.

In conclusion, the sensing node of each page buffer in a set of page buffers of implementations of the present disclosure is connected directly or indirectly to an error bit signal generating circuit through at least one first transistor. At both the stage of performing error bit counting and the stage of performing non-error bit counting, the information stored in a page buffer can be sensed through the sensing node in the page buffer and in implementations of the present disclosure multiplex the sensing nodes of the page buffers, so that the number of circuit elements in the page buffer is reduced while retaining the original functions of the page buffer, enabling miniaturization of the page buffer and reducing the area occupied by the peripheral circuit. For example, in case that the peripheral circuit has a same area, there may be more spare area for arrangement of other circuit elements, facilitating to enrich functions of the peripheral circuit.

Furthermore, the charging circuit and the control circuit of the Prechb_ver signal may be saved in the error bit signal generating circuit according to the implementations of the present disclosure, so that the number of the circuit elements can be further reduced and the area occupied by the error bit signal generating circuit and in turn the area occupied by the peripheral circuit may be further saved.

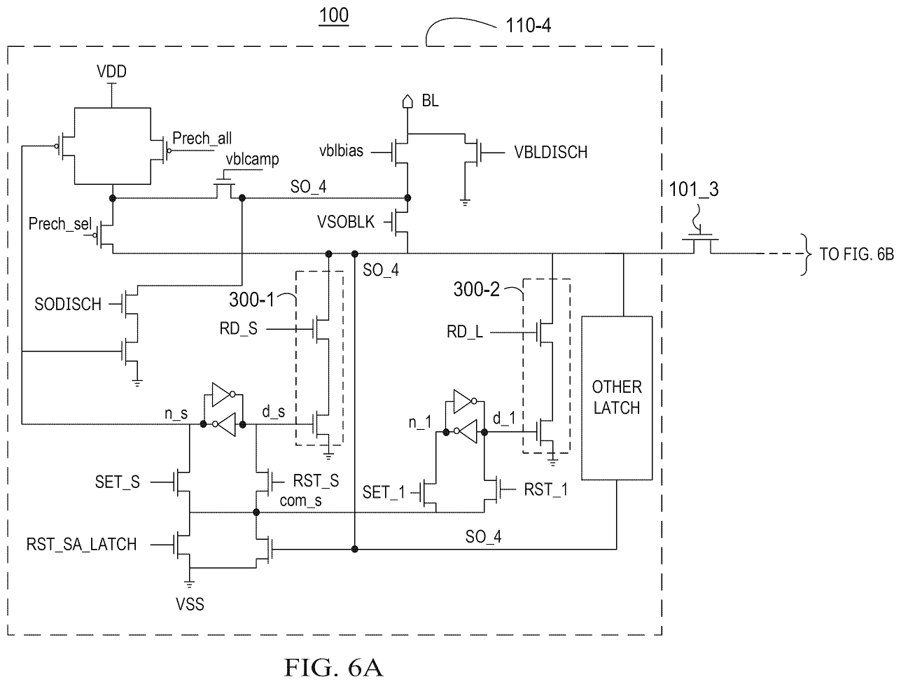

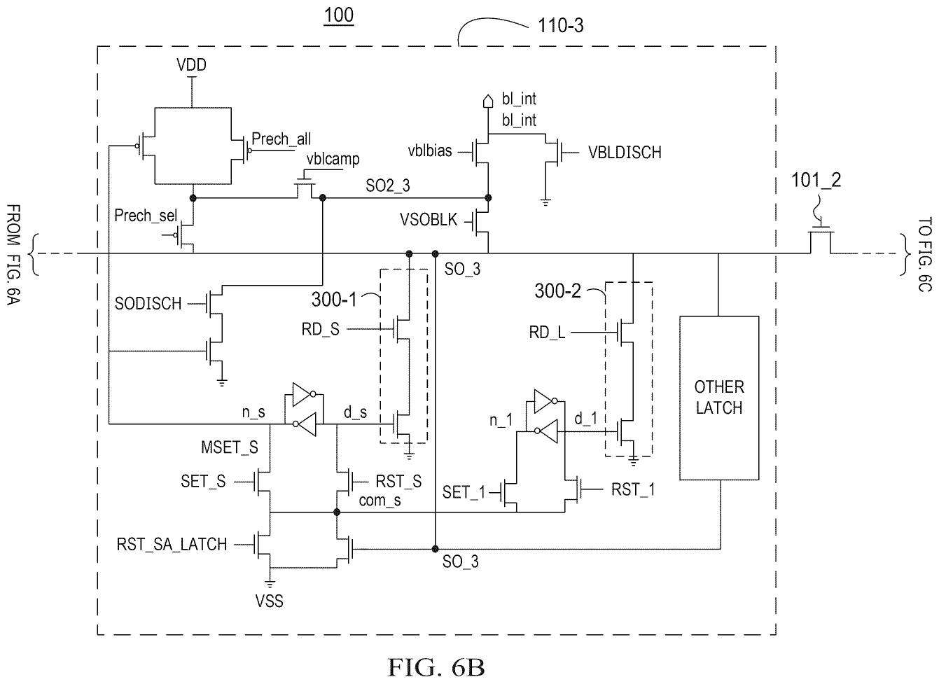

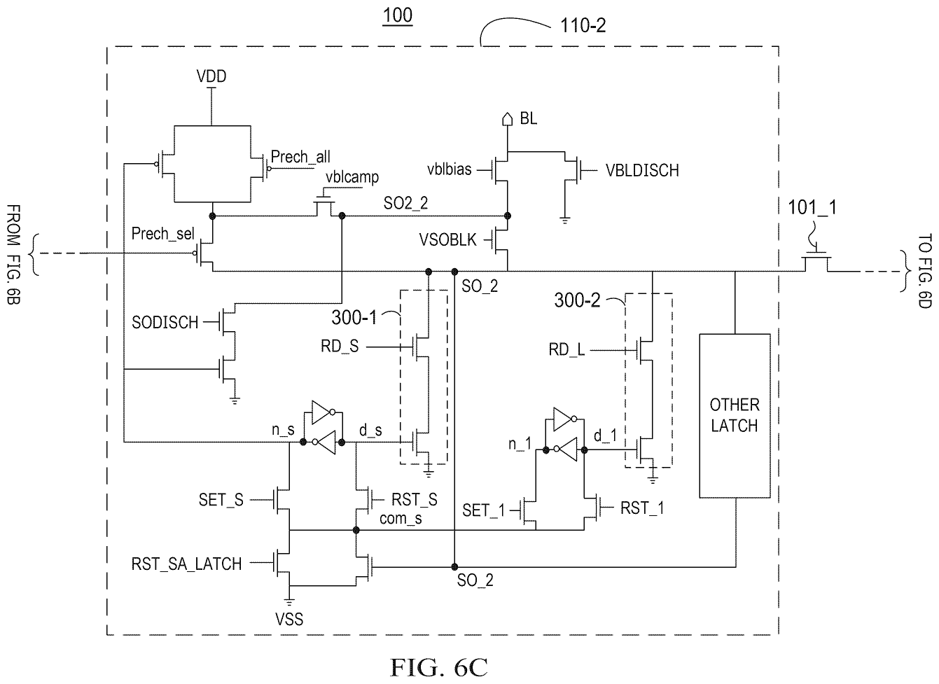

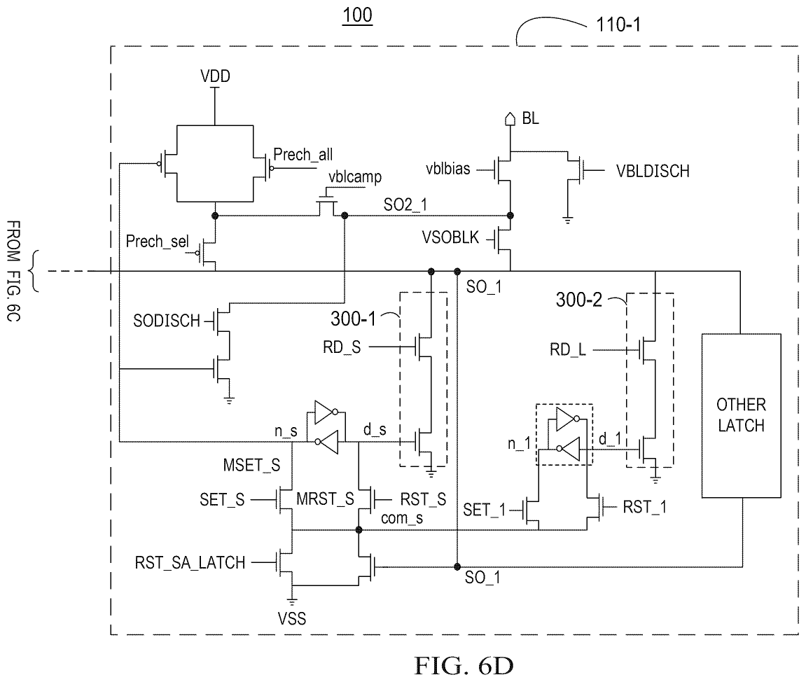

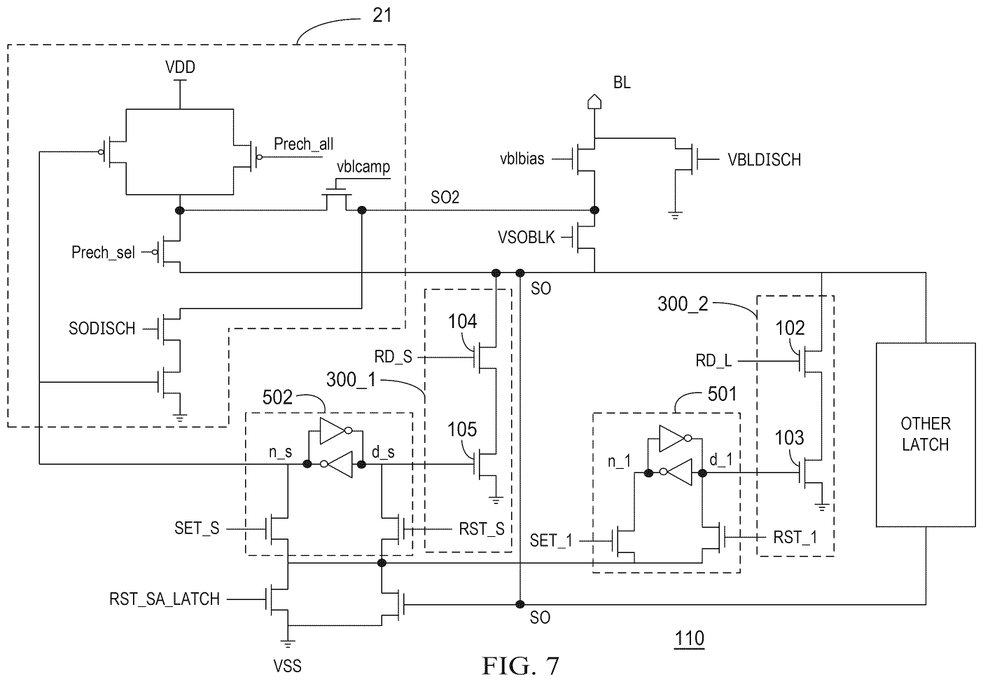

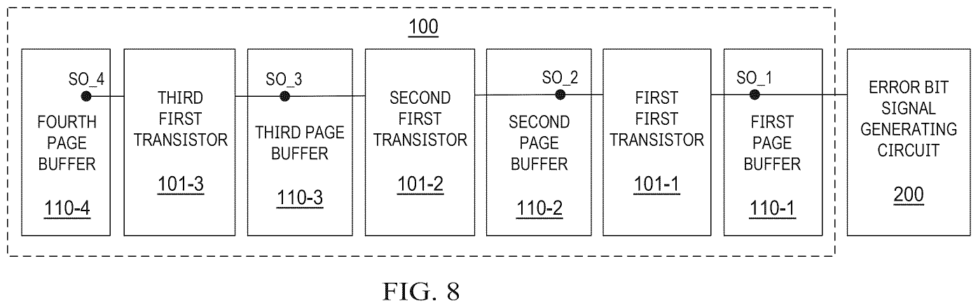

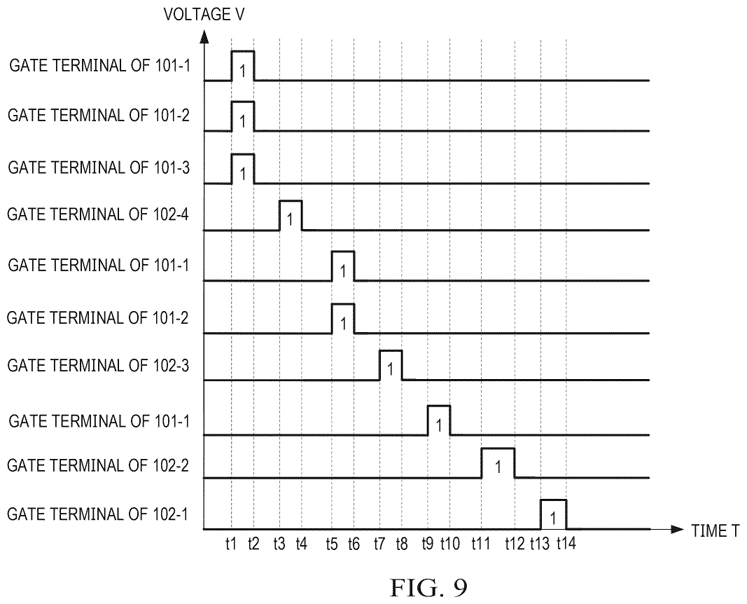

FIG. 6 is a schematic diagram of a set of page buffers 100 according to an implementation of the present disclosure and the set of page buffers 100 may include 4 page buffers 110. FIG. 7 is a schematic diagram of a page buffer 110 according to an implementation of the present disclosure, FIG. 8 is a schematic diagram illustrating a connection relationship between a set of page buffers 100 and an error bit signal generating circuit 200 according to an implementation of the present disclosure and FIG. 9 is a schematic diagram illustrating waveforms of voltages applied correspondingly during an error bit counting operation executed on the set of page buffers shown in FIG. 8 according to an implementation of the present disclosure.

Compared with the set of page buffers 100 shown in FIG. 2, the set of page buffers 100 in FIG. 6 does not include a second data transfer circuit and instead perform the error bit counting operation by multiplexing the sensing nodes. On the premise that the same functions are guaranteed, implementations of the present disclosure can reduce the number of transistors in the second data transfer circuit and in turn the circuit area. Therefore, each time a second data transfer circuit is omitted in a page buffer 110, at least one transistor may be saved. It can be understood that if a set of page buffer 100 includes N page buffers 110 with N being an integer larger than or equal to 2, at least N transistors may be saved. Since every two adjacent ones of the N page buffers 110 are also connected through a first transistor, (N−1) transistors should be added. Therefore, at least (N−(N−1)) transistors may be saved in a set of page buffers 100. Implementations of the present disclosure can reduce the area occupied by a set of page buffers 100 by reducing the number of transistors therein.

In some implementations, a set of page buffers 100 is configured to: at the stage of error bit counting operation, receive a first voltage at the sensing node of a page buffer 110 to be counted and generate a second voltage at the sensing node of the page buffer 110 based on the information stored in the page buffer 110; and
the error bit signal generating circuit 200 is configured to: at the stage of error bit counting operation, receive the second voltage and generate a current signal based on the second voltage being smaller than the first voltage.

Hereafter, the implementations above will be described with the second page buffer 110-2 in FIG. 6 as the page buffer 110 to be counted being taken as an example.

At the stage of error bit counting operation, the sensing node SO_2 of the second page buffer 110-2 receives a first voltage. In some implementations, the sensing node SO_2 may be charged by the pre-charging and pre-discharging circuit of the second page buffer 110-2, so that the sensing node SO_2 receives the first voltage (e.g., VDD). In some other implementations, the sensing node SO_2 may also be charged by an external circuit, so that the sensing node SO_2 receives the first voltage (e.g., a high voltage).

The information stored in the second page buffer 110-2 may be an information indicating a verification result. The information is stored at the n_1 node or the d_1 node of the first latch 701 shown in FIG. 7, and the data stored at the n_1 node is the inverse of that stored at the d_1 node. Implementations of the present disclosure will be explained schematically with the case that the information stored in the second page buffer is stored at the d_1 node of the first latch 701 being taken as an example. In some implementations, the first latch 701 may be a low voltage latch.

In some implementations, the first data transfer circuit connected correspondingly to the first latch 701 is turned on based on the information stored in the second page buffer 110-2, the voltage at the sensing node of the second page buffer 110-2 decreases from a first voltage (e.g., VDD) to a second voltage (e.g., VSS) and the error bit signal generating circuit 200 receives the second voltage (e.g., VSS) at the sensing node of the second page buffer 110-2 and generates a current signal.

In some implementations, the sensing node SO_2 may be charged by using an external circuit, so that the sensing node SO_2 receives the first voltage (e.g., a high voltage). Here, the high voltage is relatively high with respect to the ground voltage VSS and it can be understood that the high voltage only needs to be higher than the ground voltage VSS.

In some implementations, the first data transfer circuit connected correspondingly is turned off based on the information stored in the second page buffer 110-2, the voltage at the sensing node of the second page buffer 110-2 remains at the first voltage (e.g., VDD) and the error bit signal generating circuit 200 receives the first voltage and does not generate current signal.

Therefore, when the error bit signal generating circuit 200 according to the implementations of the present disclosure generates a current at the stage of error bit counting operation, it can indicate that the verification result stored in the page buffer that has been counted is failure. The failure of verification indicates that the data stored in the memory cell corresponding to the page buffer are failed bits and subsequently the number of the failed bits may be obtained according to the number of currents obtained statistically.

In some implementations, at the stage of error bit counting operation, the first transistors 101 between the page buffer 110 to be counted and the error bit signal generating circuit 200 are all in the on state; and
at the stage of error bit counting operation, the first transistors 101 between the page buffer 110 to be counted and the Nth page buffer 110 are all in the off state.

FIG. 8 is a schematic diagram of a set of page buffers including 4 page buffers. If the page buffer to be counted is the first page buffer 110-1, three first transistors 101 between the fourth page buffer 110-4 and the first page buffer 110-1 are in the off state.

If the page buffer 110 to be counted is the second page buffer 110-2, two first transistors 101 between the fourth page buffer 110-4 and the second page buffer 110-2 are in the off state. The one first transistor 101 between the first page buffer 110-1 and the second page buffer 110-2 is in the on state.

If the page buffer 110 to be counted is the third page buffer 110-3, the one first transistor 101 between the fourth page buffer 110-4 and the third page buffer 110-3 is in the off state. The two first transistors 101 between the first page buffer 110-1 and the third page buffer 110-3 are in the on state.

If the page buffer 110 to be counted is the fourth page buffer 110-4, three first transistors 101 between the fourth page buffer 110-4 and the first page buffer 110-1 are in the on state.

FIG. 9 is a schematic diagram illustrating waveforms of voltages applied to the gate terminals of a plurality of first transistors 101 and a plurality of second transistors 102 in a set of page buffers 100 during an error bit counting operation executed on the set of page buffers 100. Hereafter, the case of performing error bit counting on each page buffer 110 in a set of page buffers 100 will be described below in connection with FIGS. 6, 7 and 8.

In some implementations, the error bit counting operation may be performed on the fourth page buffer 110-4, the third page buffer 110-3, the second page buffer 110-2 and the first page buffer 110-1 in FIG. 7 successively. In some other implementations, the error bit counting operation may also be performed on the plurality of page buffers 110 in the set of page buffers 100 in another order. The present disclosure is not limited in this aspect.

In the time period from t1 to t2, by applying turn-on voltages to the gate terminals of the three first transistors 101 between the fourth page buffer 110-4 and the first page buffer 110-1, the three first transistors are in the on state.

In the time period from t3 to t4, a turn-on voltage is applied to the gate terminal of the second transistor 102 in the fourth page buffer 110-4.

Before t3 (including the time period before t1), the sensing node of the fourth page buffer 110-4 also needs to be charged to a first voltage (e.g., VDD).

Therefore, the error bit counting operation can be performed on the fourth page buffer 110-4 with the aid of the error bit signal generating circuit coupled to the fourth page buffer 110-4.

In the time period from t5 to t6, by applying turn-on voltages to the gate terminals of the two first transistors 101 between the third page buffer 110-3 and the first page buffer 110-1, the two first transistors are in the on state. By not applying a turn-on voltage to the gate terminal of the one first transistor 101 between the third page buffer 110-3 and the fourth page buffer 110-4, the one first transistor is in the off state.

In the time period from t7 to t8, a turn-on voltage is applied to the gate terminal of the second transistor 102 in the third page buffer 110-3.

In the time period from the time at which the error bit counting performed on the fourth page buffer 110-4 terminates to t7, the sensing node of the third page buffer 110-3 also needs to be charged to the first voltage (e.g., VDD).

Therefore, the error bit counting operation can be performed on the third page buffer 110-3 with the aid of the error bit signal generating circuit coupled to the third page buffer 110-3.

In the time period from t9 to t10, by applying a turn-on voltage to the gate terminal of the one first transistor 101 between the second page buffer 110-2 and the first page buffer 110-1, the one first transistor is in the on state. By not applying turn-on voltages to the gate terminals of the two first transistors 101 between the second page buffer 110-2 and the fourth page buffer 110-4, the two first transistors are in the off state.

In the time period from t11 to t12, a turn-on voltage is applied to the gate terminal of the second transistor 102 in the second page buffer 110-2.

In the time period from the time at which the error bit counting performed on the third page buffer 110-3 terminates to t11, the sensing node of the second page buffer 110-2 also needs to be charged to the first voltage (e.g., VDD).

Therefore, the error bit counting operation can be performed on the second page buffer 110-2 with the aid of the error bit signal generating circuit coupled to the second page buffer 110-2.

In the time period from t13 to t14, a turn-on voltage is applied to the gate terminal of the second transistor 102 in the first page buffer 110-1.

In the time period from the time at which the error bit counting performed on the second page buffer 110-2 terminates to t13, the sensing node of the first page buffer 110-1 also needs to be charged to the first voltage (e.g., VDD).

Therefore, the error bit counting operation can be performed on the first page buffer 110-1 with the aid of the error bit signal generating circuit coupled to the first page buffer 110-1.

Therefore, in implementations of the present disclosure, error bit counting can be performed on the page buffer 110 to be counted by controlling the state of the first transistor(s) 101 between the page buffer 110 to be counted and the error bit signal generating circuit 200 and the state of the first transistor(s) 101 between the page buffer 110 to be counted and the Nth page buffer 110.

In some implementations, at the stage of non-error bit counting operations, the plurality of first transistors 101 are all in the off state.

At the stage of error bit counting operation, page buffers 110 may be configured for error bit counting.

At the stage of non-error bit counting operations, page buffers 110 may be configured for programming, verification or other operations and in these operations the individual page buffer 110 in the set of page buffers 100 need not to be connected with the error bit signal generating circuit 200 directly or indirectly. Therefore, the first transistors 101 between the individual page buffer 110 in the set of page buffers 100 and the error bit signal generating circuit 200 are all in the off state.

FIG. 7 is a structural diagram of a page buffer in a set of page buffers according to an implementation of the present disclosure.

In some implementations, as shown in FIG. 7, the page buffer includes: a first latch 701, a second transistor 102 and a third transistor 103. The first terminal of the second transistor 102 is connected to the sensing node, the second terminal of the second transistor is connected to the first terminal of the third transistor 103 and the second terminal of the third transistor 103 is connected to the second power voltage (e.g., the ground voltage VSS). In implementations of the present disclosure, the circuit composed of the second transistor 102 connected in series with the third transistor 103 is referred to as a first data transfer circuit.

The page buffer 110 to be counted is configured to: turn on the second transistor 102 at the stage of error bit counting operation, and receive the information stored in the first latch 701 at the gate terminal of the third transistor 103.

At the stage of error bit counting operation, the sensing node of the page buffer 110 to be counted is charged to the first voltage (e.g., VDD), and at this point the second transistor 102 of the page buffer 110 to be counted is turned on and the gate terminal of the third transistor 103 receives the information stored at the node d_1 in the first latch 701. If the information makes the third transistor 103 turned on, the first data transfer circuit, in which the second transistor 102 and the third transistor 103 are located, is turned on, so that the voltage at the sensing node of the page buffer to be counted transits from the first voltage (VDD) to the second voltage (VSS). If the information makes third transistor 103 turned off, the first data transfer circuit, in which the second transistor 102 and the third transistor 103 are located, is turned off, so that the voltage at the sensing node of the page buffer to be counted remains at first voltage (VDD). In implementations of the present disclosure, at the stage of error bit counting operation, in order to enable error bit counting of the page buffer to be counted, the second transistor 102 of the page buffer 110 to be counted needs to be turned on.

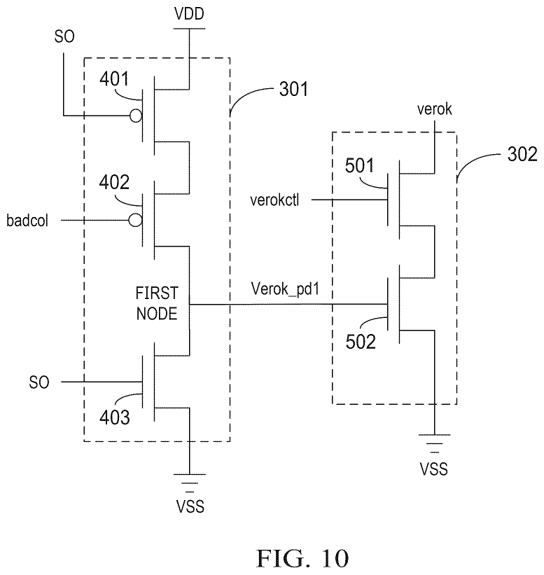

In some implementations, as shown in FIG. 10, the error bit signal generating circuit includes a first branch 301 and a second branch 302.

At the stage of error bit counting operation, the first branch is configured to: receive the second voltage and generate a first control signal at a first level for turning on the second branch 302 based on the second voltage being smaller than the first voltage.

The second branch 302 is configured to receive the first control signal at the first level and generate the current signal.

In implementations of the present disclosure, at the stage of error bit counting operation, the first control signal at the first level is output at the output terminal of the first branch 301 based on the second voltage which is smaller than the first voltage and is received at the input terminal of the first branch 301.

The first control signal at the first level is received at the input terminal of the second branch 302 and the current signal is generated at the output terminal of the second branch 302.

In implementations of the present disclosure, at the stage of error bit counting operation, the first control signal at a second level is output at the output terminal of the first branch 301 based on the second voltage which is equal to the first voltage and received at the input terminal of the first branch 301.

The first control signal at the second level is received at the input terminal of the second branch 302 and the current signal is not generated at the output terminal of the second branch 302.

In implementations of the present disclosure, the first level may be a high level and the second level may be a low level. In some other implementations, the first level may be a low level and the second level may be a high level. This is related to the specific types of the transistors in the second branch 302 and the present disclosure is not limited in this aspect.

In some implementations, as shown in FIG. 10, the first branch includes a fourth transistor 401, a fifth transistor 402 and a sixth transistor 403, wherein the first terminal of the fourth transistor 401 is configured to receive a first power voltage, the second terminal of the fourth transistor 401 is connected to the first terminal of the fifth transistor 402, the second terminal of the fifth transistor 402 and the first terminal of the sixth transistor 403 are connected to a first node and the second terminal of the sixth transistor 403 is configured to receive a second power voltage.

At the stage of error bit counting operation, the fifth transistor 402 is in the on state, the gate terminal of the fourth transistor 401 and the gate terminal of the sixth transistor 403 are configured to receive the second voltage. If the second voltage is smaller than the first voltage, the first control signal at the first level is generated at the first node.

It can be understood that the first node is the connection point between the first branch 301 and the second branch 302.

The first voltage source voltage may be a power voltage (e.g., VDD) and the second voltage source voltage may be a ground voltage (e.g., VSS).

The gate terminal of the fourth transistor 401 and the gate terminal of the sixth transistor 403 are connected with the sensing node of the transistor to be counted, and when the second voltage received at the sensing node of the transistor to be counted is smaller than the first voltage, one of the fourth transistor 401 and the sixth transistor 403 is turned on and the other of them is turned off, and a first control signal at a first level that may turn on the second branch 302 is generated at the first node.

In some implementations, the fourth transistor 401 may be a P-type transistor, the sixth transistor 403 may be an N-type transistor, and the type of the fifth transistor 402 is independent of the types of the fourth transistor 401 and the sixth transistor 403 and may be an N-type or a P-type. In some other implementations, the fourth transistor 401 may be an N-type transistor, the sixth transistor 403 may be a P-type transistor, and the type of the fifth transistor 402 is independent of the types of the fourth transistor 401 and the sixth transistor 403 and may be an N-type or a P-type.

In some implementations, as shown in FIG. 10, the second branch 302 includes: a seventh transistor 501 and an eighth transistor 502, wherein the first terminal of the seventh transistor 501 is connected to the first terminal of the eighth transistor 502 and the second terminal of the eighth transistor 502 is connected to the second power voltage.

At the stage of error bit counting operation, the seventh transistor 501 is in the on state, the gate terminal of the eighth transistor 502 is configured to receive the first control signal and the current signal is generated when the first control signal is at the first level.

In implementations of the present disclosure, the seventh transistor 501 may be an N-type transistor or a P-type transistor.

At the stage of error bit counting operation, the seventh transistor 501 is in the on state and if the eighth transistor 502 is in the on state, the second branch is turned on and a current signal is generated in the second branch. When the eighth transistor 502 receives the first control signal at the first level, the eighth transistor 502 is turned on. If the eighth transistor 502 is in the off state, the second branch is off and no current signal is generated in the second branch. When the eighth transistor 502 receives the first control signal at the second level, the eighth transistor 502 is turned off.

In some implementations, the peripheral circuit further includes:
a reference signal output circuit configured to output a plurality of reference signals;
a current-voltage conversion circuit connected with the plurality of error bit signal generating circuits and configured to receive the plurality of current signals and generate voltage signals based on the plurality of current signals; and
a comparator circuit connected to the current-voltage conversion circuit and the reference signal output circuit and configured to receive and compare the voltage signals and at least one reference signal and output comparison results.

In an implementation of the present disclosure, the reference signal may be a current signal or a voltage signal and implementations of the present disclosure will be described with a voltage signal taken as the reference signal.

A plurality of sets of page buffers are connected with a plurality of error bit signal generating circuits, which are then connected to the current-voltage conversion circuit. The current-voltage conversion circuit receives a plurality of current signals and outputs corresponding voltage signals. In some implementations, the greater the received plurality of current signals are, the greater the voltage signals obtained by the conversion are. In some other implementations, the greater the received plurality of current signals are, the smaller the voltage signals obtained by the conversion are.

The comparator circuit is connected with the current-voltage conversion circuit and the reference signal output circuit and compares the voltage signals with a plurality of reference signals. Since each reference signal represents an interval of number of error bits, the intervals of number of error bits corresponding to the plurality of sets of page buffers may be found by finding the respective reference signal nearest to the voltage signal, so that the number of error bits of the plurality of sets of page buffers may be obtained.

In some implementations, each page buffer further includes: a pre-charging and pre-discharging circuit connected with a power source terminal and a sensing node and configured to charge the sensing node of the page buffer to be counted to the first voltage at the stage of error bit counting operation.

In some implementations, as shown in FIG. 7, the page buffer 110 further includes: a pre-charging and pre-discharging circuit 21 connected with a power source terminal VDD and a sensing node SO, respectively. The pre-charging and pre-discharging circuit 21 may be configured to adjust a bit line voltage during programming. For example, a voltage is applied to a bit line to pre-charge the bit line; or the voltage of the bit line is pull down to the ground voltage to discharge the bit line.

In some implementations, during programming of a memory cell, a program-prohibiting bit line voltage (e.g., VDD) or a normal program bit line voltage (e.g., VSS) is applied to the bit line connected with the memory cell through the pre-charging and pre-discharging circuit 21. Illustratively, a high level is applied to the bit line through the charging function of the pre-charging and pre-discharging circuit 21 to prohibit programming, or the bit line is discharged through the discharging function of the pre-charging and pre-discharging circuit 21 to pull the voltage of the bit line down to the ground voltage and in turn permit programming.

In an implementation of the present disclosure, at the stage of error bit counting operation, the sensing node of the page buffer to be counted is charged to the first voltage through the pre-charging and pre-discharging circuit 21 in the page buffer to be counted. For example, a Prech_all signal and a Prech_sel signal may be enabled to charge the sensing node to the first voltage VDD.

In an implementation of the present disclosure, charging may be performed in other ways, so that the charging circuit in the error bit signal generating circuit may be saved and the number of transistors may be reduced.

In some implementations, as shown in FIG. 7, the page buffer further includes: a second latch 702, a ninth transistor 104 and a tenth transistor 105, wherein the first terminal of the ninth transistor 104 is connected to the sensing node, the second terminal of the ninth transistor 104 is connected to the first terminal of the tenth transistor 105, the second terminal of the tenth transistor 105 is connected to a second power source voltage, and the gate terminal of the tenth transistor is connected to the second latch.

The second latch 702 is configured to store programming information or verification information.

The gate terminal of the ninth transistor 104 is configured to receive a read signal.

In some implementations, at the stage of non-error bit counting operation, the programming information or the verification information stored in the second latch 702 is read based on the ninth transistor 104 being turned on.

In some implementations, the second latch may be a sense latch.

In some implementations, the information stored in the first latch 701 may also come from the second latch 702. For example, the verification information stored in the second latch 702 may be transferred to the first latch 701 and then the error bit counting operation is performed to read the verification information.

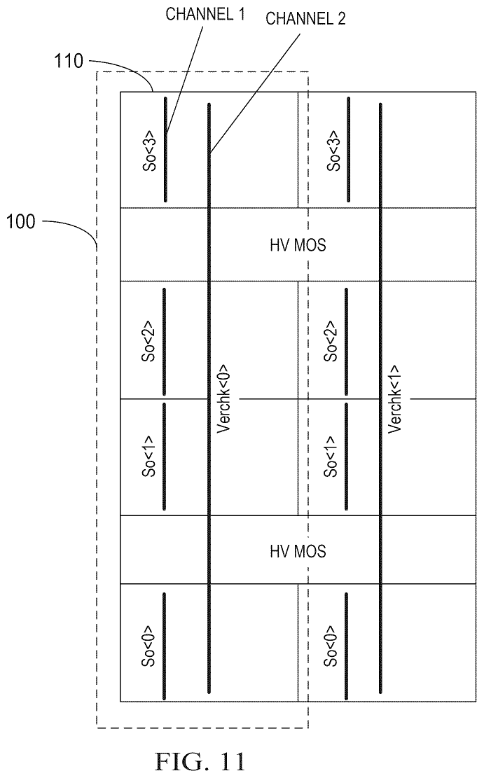

FIG. 11 is a schematic diagram illustrating channel distribution of the set of page buffers in the implementation shown in FIG. 2 and the error bit signal generating circuit shown in FIG. 3. It can be seen that the channel connected with the sensing node of each page buffer in the set of page buffers is different from the channel connected with the VERCHK signal in the error bit signal generating circuit, e.g., two channels are occupied.

In some implementations, as shown in FIG. 7, the N page buffers in the set of page buffers are arranged in a first direction, the error bit signal generating circuit is connected with the sensing node of the first page buffer in the set of page buffers, the distance between the first page buffer in the set of page buffers and the error bit signal generating circuit is smaller than the distance between any other page buffer in the set of page buffers and the error bit signal generating circuit.

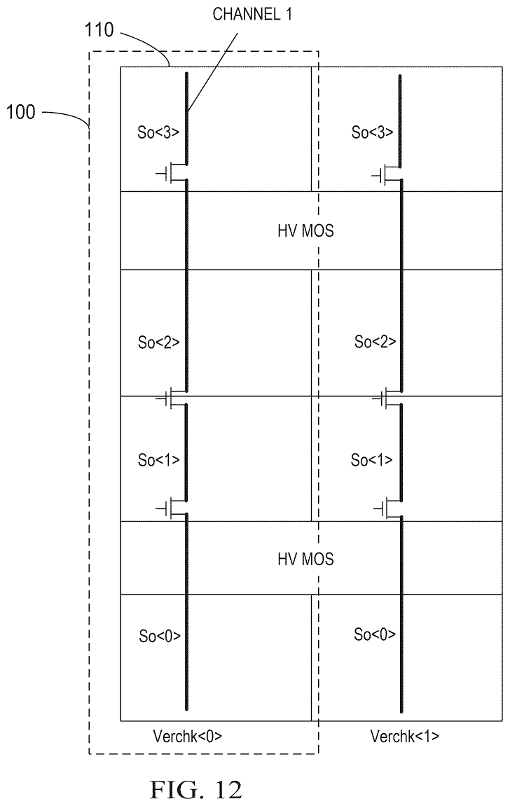

FIG. 12 is a schematic diagram illustrating channel distribution of a set of page buffers and an error bit signal generating circuit according to an implementation of the present disclosure. It can be seen that the channel connected with the sensing node of each page buffer in the set of page buffers is the same as the channel connected with the VERCHK signal in the error bit signal generating circuit. For example, in contrast to the implementation shown in FIG. 11, in this implementation of the present disclosure, by arranging the N page buffers in the set of page buffers and the error bit signal generating circuit in the first direction, the number of channels may be reduced and metal wiring may be saved.

The layout corresponding to each page buffer in FIGS. 11 and 12 may include a PB_CACHE region and a PB_LV region (not shown), wherein a cache latch is placed in the PB_CACHE region and one or more of a sense latch, a low voltage latch, a D1 latch and a D2 latch are placed in the PB_LV region.

In FIGS. 11 and 12, high voltage metal-oxide-semiconductor field-effect transistors (HV MOS) may be further disposed between the page buffers of the set of page buffers.

Implementations of the present disclosure further provide a memory system 30 including the memory device 34 in any of the implementations described above and a memory controller 32 coupled to the memory device 34.

The memory controller 32 is configured to control the memory device 34.

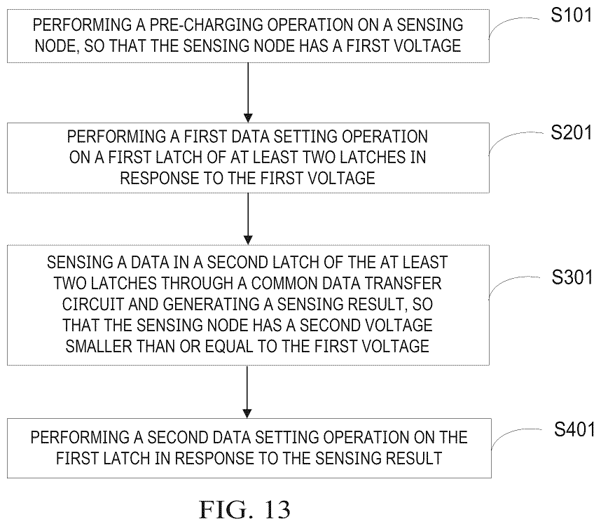

Implementations of the present disclosure further provide a method of operating a memory device. As shown in FIG. 13, the method includes the following operations.

in operation S1, at the stage of error bit counting operation, a first voltage is received at the sensing node of a page buffer to be counted.

In some implementations, the sensing node may be charged based on the pre-charging and pre-discharging circuit of the page buffer, so that a first voltage (e.g., VDD) is received at the sensing node. In some other implementations, the sensing node may also be charged by using an external circuit, so that the first voltage (e.g., a high voltage) is received at the sensing node. Here, the high voltage is relatively high with respect to the ground voltage VSS.

In operation S2, after the first voltage is received at the sensing node, a second voltage is generated at the sensing node of the page buffer to be counted based on the information stored in the page buffer.

In the implementation of the present disclosure, a second voltage which is equal to or smaller than the first voltage may be generated at the sensing node of the page buffer to be counted based on the information stored in the page buffer.

In operation S3, the error bit signal generating circuit receives the second voltage and generates a current signal based on the second voltage being smaller than the first voltage.

In an implementation of the present disclosure, at both the stage of performing error bit counting and the stage of performing non-error bit counting, the information stored in a page buffer can be sensed through the sensing node in the page buffer and in implementations of the present disclosure, by multiplexing the sensing node of the page buffer, the number of circuit elements in the page buffer is reduced while retaining the original functions of the page buffer, enabling miniaturization of the page buffer and reducing the area occupied by the peripheral circuit. For example, in case that the peripheral circuit has the same area, there may be more spare area for arrangement of other circuit elements, facilitating to enrich functions of the peripheral circuit.

In some implementations, a plurality of page buffers constitutes a set of page buffers, and the respective sensing node of two adjacent page buffers in the set of page buffers is connected through a first transistor.

The method further includes: at the stage of error bit counting operation, turning on the first transistor between the page buffer to be counted and the error bit signal generating circuit; and
at the stage of error bit counting operation, turning off the first transistors between the page buffer to be counted and the Nth page buffer.

In some implementations, the method further includes: at the stage of non-error bit counting operations, turning off the plurality of first transistors.

In some implementations, the page buffer includes: a first latch, a second transistor and a third transistor, the first terminal of the second transistor is connected to the sensing node, the second terminal of the second transistor is connected to the first terminal of the third transistor and the second terminal of the third transistor is connected to the second power voltage.

The generating the second voltage at the sensing node of the page buffer based on the information stored in the page buffer includes:
at the stage of error bit counting operation, turning on the second transistor in the page buffer to be counted, receiving the information stored in the first latch at the gate terminal of the third transistor and generating the second voltage at the sensing node of the page buffer.

In some implementations, receiving the second voltage and generating a current signal based on the second voltage being smaller than the first voltage includes:
receiving the second voltage by the first branch of the error bit signal generating circuit and generating a first control signal at a first level for turning on the second branch of the error bit signal generating circuit based on the second voltage being smaller than the first voltage; and
receiving the first control signal at the first level by the second branch of the error bit signal generating circuit and generating the current signal.

In some implementations, receiving the second voltage by the first branch of the error bit signal generating circuit and generating a first control signal at a first level for turning on the second branch based on the second voltage being smaller than the first voltage includes:
at the stage of error bit counting operation, turning on the fifth transistor, receiving the second voltage at the gate terminal of the fourth transistor and the gate terminal of the sixth transistor and generating the first control signal at the first level based on the second voltage being smaller than the first voltage.

In some implementations, receiving the first control signal at the first level by the second branch of the error bit signal generating circuit and generating the current signal includes:
at the stage of error bit counting operation, turning on the seventh transistor, receiving the first control signal at the first level by the gate terminal of the eighth transistor and generating the current signal.

In some implementations, the method further includes:
outputting a plurality of reference signals by a reference signal output circuit;
receiving a plurality of current signals and outputting voltage signals based on the plurality of current signals by a current-voltage conversion circuit; and
receiving and comparing the voltage signals and at least one reference signal and outputting comparison results by a comparator circuit.

In some implementations, receiving the first voltage at the sensing node of the page buffer includes:
at the stage of error bit counting operation, charging the sensing node of the page buffer to be counted to the first voltage based on the pre-charging and pre-discharging circuit.

Regarding the method in the above implementations, specific implementations have been described in detail in the implementations of the products corresponding to the method and will not be described repeatedly.

It should be understood that “one implementation” or “an implementation” mentioned throughout the specification means that particular features, structures or characteristics in association with the implementation is included in at least one implementation. Therefore, “in one implementation” or “in an implementation” mentioned throughout the specification refers not necessarily to the same implementation. Moreover, those particular features, structures or characteristics may be incorporated in one or more implementations in any suitable manner. It should be understood that, in various implementations of the present disclosure, the ordinal numbers of the various processes above are not intended to indicate that the processes must be performed in the sequential order, and the various processes should be performed in a sequential order determined depending on their functions and inherent logic. Implementation of the present disclosure is not limited in this respect. The ordinal numbers in the above-mentioned implementations of the present disclosure are only for the purpose of description and imply no preference for any one or more implementations over the others.

It is to be noted that, terms “include”, “comprise” or any other variants thereof are intended to encompass non-exclusive inclusion such that a process, method, article or device including a series of elements includes not only those elements, but also other elements that have not been listed explicitly, or further includes elements inherent in the process, method, article or device. Without any further limitations, an element defined by expression “including a . . . ” does not exclude additional identical elements in the process, method, article or device including the element.

What have been described above are only implementations of the present disclosure. However, the scope of the present disclosure is not limited thereto, and variations or substitutions that easily occur to those skilled in the art in light of the technical contents disclosed by the present disclosure will fall within the scope of the present disclosure. Therefore, the scope of the present disclosure should be determined by the scope of the claims.

What is claimed is:

1. A memory device, comprising:
a peripheral circuit that comprises a set of page buffers, an error bit signal generating circuit and a plurality of first transistors, wherein the set of page buffers comprises N page buffers with N being an integer larger than 1, the error bit signal generating circuit is connected with sensing nodes of the page buffers, and respective sensing nodes of every two adjacent page buffers in the set of page buffers are connected with one of the first transistors.

2. The memory device of claim 1, wherein the N page buffers in the set of page buffers are arranged in a first direction, the error bit signal generating circuit is connected with a sensing node of a first of the page buffers in the set of page buffers, a distance between a first page buffer in the set of page buffers and the error bit signal generating circuit is smaller than a distance between any other page buffer in the set of page buffers and the error bit signal generating circuit.

3. The memory device of claim 1, wherein the set of page buffers is configured to, at a stage of error bit counting operation, receive a first voltage at a sensing node of a page buffer to be counted and generate a second voltage at the sensing node of the page buffer based on an information stored in the page buffer; and
the error bit signal generating circuit is configured to, at the stage of error bit counting operation, receive the second voltage and generate a current signal based on the second voltage being smaller than the first voltage.

4. The memory device of claim 3, wherein
at the stage of error bit counting operation, the first transistors between the page buffer to be counted and the error bit signal generating circuit are all in an on state; and
at the stage of error bit counting operation, the first transistors between the page buffer to be counted and the Nth page buffer are all in an off state.

5. The memory device of claim 1, wherein at a stage of non-error bit counting operation, the plurality of first transistors are all in an off state.

6. The memory device of claim 3, wherein the page buffer to be counted comprises a first latch, a second transistor and a third transistor, a first terminal of the second transistor is connected to the sensing node, a second terminal of the second transistor is connected to a first terminal of the third transistor and a second terminal of the third transistor is connected to a second power source voltage; and
the page buffer to be counted is configured to turn on the second transistor at the stage of error bit counting operation, and receive an information stored in the first latch at a gate terminal of the third transistor.

7. The memory device of claim 3, wherein the error bit signal generating circuit comprises a first branch and a second branch, wherein
at the stage of error bit counting operation, the first branch is configured to receive the second voltage and generate a first control signal at a first level for turning on the second branch based on the second voltage being smaller than the first voltage; and
the second branch is configured to receive the first control signal at the first level and generate the current signal.

8. The memory device of claim 7, wherein the first branch comprises a fourth transistor, a fifth transistor and a sixth transistor, a first terminal of the fourth transistor is configured to receive a first power source voltage, a second terminal of the fourth transistor is connected to a first terminal of the fifth transistor, a second terminal of the fifth transistor and a first terminal of the sixth transistor are connected to a first node and a second terminal of the sixth transistor is configured to receive a second power source voltage; and
at the stage of error bit counting operation, the fifth transistor is in an on state, a gate terminal of the fourth transistor and a gate terminal of the sixth transistor are configured to receive the second voltage, and if the second voltage is smaller than the first voltage, the first control signal at the first level is generated at the first node.

9. The memory device of claim 8, wherein the second branch comprises a seventh transistor and an eighth transistor, a first terminal of the seventh transistor is connected to a first terminal of the eighth transistor and a second terminal of the eighth transistor is connected to the second power source voltage; and
at the stage of error bit counting operation, the seventh transistor is in an on state, a gate terminal of the eighth transistor is configured to receive the first control signal and the current signal is generated when the first control signal is at the first level.

10. The memory device of claim 3, wherein the peripheral circuit further comprises:
a reference signal output circuit configured to output a plurality of reference signals;
a current-voltage conversion circuit connected with the error bit signal generating circuit and configured to receive the current signal and output a voltage signal based on the current signal; and
a comparator circuit connected to the current-voltage conversion circuit and the reference signal output circuit and configured to receive and compare the voltage signal and at least one of the plurality of reference signals and output comparison results.

11. The memory device of claim 3, wherein the page buffer to be counted further comprises:
a pre-charging and pre-discharging circuit connected with a power source terminal and the sensing node and configured to charge the sensing node of the page buffer to be counted to the first voltage at the stage of error bit counting operation.

12. The memory device of claim 3, the page buffer to be counted further comprises a second latch, a ninth transistor and a tenth transistor, wherein a first terminal of the ninth transistor is connected to the sensing node of the page buffer to be counted, a second terminal of the ninth transistor is connected to a first terminal of the tenth transistor, a second terminal of the tenth transistor is connected to a second power source voltage, and a gate terminal of the tenth transistor is connected to the second latch;
the second latch is configured to store a programming information or a verification information; and
a gate terminal of the ninth transistor is configured to receive a read signal.

13. A memory system comprising:
a memory device comprising a peripheral circuit that comprises a set of page buffers, an error bit signal generating circuit and a plurality of first transistors, wherein the set of page buffers comprises N page buffers with N being an integer larger than 1, the error bit signal generating circuit is connected with sensing nodes of the page buffers, and respective sensing nodes of every two adjacent page buffers in the set of page buffers are connected with one of the first transistors; and
a memory controller coupled to the memory device,
wherein the memory controller is configured to control the memory device.

14. A method of operating a memory device, comprising:
at a stage of error bit counting operation, receiving a first voltage at a sensing node of a page buffer to be counted;
after the first voltage is received at the sensing node, generating a second voltage at the sensing node of the page buffer to be counted based on an information stored in the page buffer; and
receiving a second voltage by an error bit signal generating circuit and generating a current signal based on the second voltage being smaller than the first voltage.

15. The method of claim 14, wherein a plurality of page buffers constitutes a set of page buffers, and the respective sensing nodes of two adjacent page buffers in the set of page buffers are connected through a first transistor; and
the method further comprises:
at the stage of error bit counting operation, turning on the first transistors between the page buffer to be counted and the error bit signal generating circuit; and
at the stage of error bit counting operation, turning off the first transistors between the page buffer to be counted and the Nth page buffer.

16. The method of claim 15, further comprising:
at a stage of non-error bit counting operations, turning off the first transistors.

17. The method claim 14, wherein the page buffer comprises a first latch, a second transistor and a third transistor, a first terminal of the second transistor is connected to the sensing node, a second terminal of the second transistor is connected to a first terminal of the third transistor and a second terminal of the third transistor is connected to a second power source voltage; and
the generating the second voltage at the sensing node of the page buffer based on the information stored in the page buffer comprises:
at the stage of error bit counting operation, turning on the second transistor in the page buffer to be counted, receiving the information stored in the first latch at a gate terminal of the third transistor and generating the second voltage at the sensing node of the page buffer.

18. The method of claim 14, wherein the receiving the second voltage and the generating the current signal based on the second voltage being smaller than the first voltage comprises:
receiving the second voltage by a first branch of the error bit signal generating circuit and generating a first control signal at a first level for turning on a second branch of the error bit signal generating circuit based on the second voltage being smaller than the first voltage; and
receiving the first control signal at the first level by the second branch of the error bit signal generating circuit and generating the current signal.

19. The method of claim 18, wherein
the receiving the second voltage by the first branch of the error bit signal generating circuit and generating a first control signal at a first level for turning on the second branch based on the second voltage being smaller than the first voltage comprises:
at the stage of error bit counting operation, turning on a fifth transistor, receiving the second voltage at a gate terminal of a fourth transistor and a gate terminal of a sixth transistor and generating the first control signal at the first level based on the second voltage being smaller than the first voltage.

20. The method of claim 19, wherein the receiving the first control signal at the first level by the second branch of the error bit signal generating circuit and generating the current signal comprises:
at the stage of error bit counting operation, turning on a seventh transistor, receiving the first control signal at the first level by a gate terminal of an eighth transistor and generating the current signal.
